(19) United States
(12) Patent Application Publication
(10) Pub. No.: US 2025/0232096 A1
(43) Pub. Date: Jul. 17, 2025

(54) DETERMINING DEVICE

(71) Applicant: TOYOTA JIDOSHA KABUSHIKI KAISHA, Toyota-shi (JP)

(72) Inventor: Masaaki Yamaoka, Tokyo-to (JP)

(73) Assignee: TOYOTA JIDOSHA KABUSHIKI KAISHA, Toyota-shi (JP)

(21) Appl. No.: 19/017,966

(22) Filed: Jan. 13, 2025

(30) Foreign Application Priority Data
Jan. 17, 2024 (JP) 2024-005281

(51) Int. Cl. G06F 30/27; G08G 1/16

(52) U.S. Cl. CPC G06F 30/27; G08G 1/166

(57) ABSTRACT

A vehicle control device has a processor configured to carry out determination processing of whether a pedestrian will enter a road based on road information representing a road and pedestrian information representing a pedestrian, in a predetermined range in a traveling direction of a vehicle, generate status information representing a status of a driver driving the vehicle or the vehicle that can be confirmed by the pedestrian during a predetermined period in the past, based on information representing the driver of the vehicle or motion of the vehicle, change criterion for the determination processing based on the generated status information so that it is easier to determine that the pedestrian will enter the road or that the pedestrian will not enter the road, and wherein the determination processing is carried out whether the pedestrian will enter the road using the changed criterion.

### CROSS-REFERENCE TO RELATED APPLICATIONS

This application claims priority to Japanese Patent Application No. 2024-005281 filed Jan. 17, 2024, the entire contents of which are herein incorporated by reference.

### FIELD

The present disclosure relates to a determining device.

### BACKGROUND

A pedestrian may cross a road in front of a moving vehicle. The driver operates the vehicle while observing the status of the pedestrian (e.g., see Japanese Unexamined Patent Publication No. 2005-332297). The pedestrian, in turn, looks at the vehicle and determines the timing at which to cross the road.

In this way, the motion of the vehicle may affect the motion of the pedestrian, and the motion of the pedestrian may affect the motion of the vehicle.

By repeatedly considering the motion of the pedestrian and the motion of the vehicle, it may be possible to accurately determine whether the pedestrian will cross the road.

### SUMMARY

However, at present, repeated consideration of the motion of the pedestrian and the motion of the vehicle has not been carried out. Based on the status of the pedestrian up to the time of determination, it is determined whether the pedestrian will enter the road or not.

As a result, it was sometimes impossible to accurately determine whether a pedestrian would enter the road or not. Therefore, it is believed that the interaction between the motion of the pedestrian and the motion of the vehicle can be used to more accurately determine whether the pedestrian will enter the road.

The pedestrian observes the motion of the driver or vehicle to determine the timing at which to cross the road. Therefore, the status of the driver or the vehicle that can be confirmed by the pedestrian becomes information for determining the motion of the pedestrian.

The present disclosure aims to provide a determining device capable of determining whether a pedestrian will enter a road based on the status of a driver or a vehicle that can be confirmed by the pedestrian together with the status of the pedestrian.

(1) According to one embodiment, a determining device is provided. The determining device has a processor configured to carry out determination processing of whether a pedestrian will enter a road based on road information representing a road and pedestrian information representing a pedestrian, in a predetermined range in a traveling direction of a vehicle, generate status information representing a status of a driver driving the vehicle or the vehicle that can be confirmed by the pedestrian during a predetermined period in the past, based on information representing the driver of the vehicle or motion of the vehicle, change criterion for the determination processing based on the generated status information so that it is easier to determine that the pedestrian will enter the road or that the pedestrian will not enter the road, and wherein the determination processing is carried out whether the pedestrian will enter the road using the changed criterion.

(2) In the determining device of embodiment (1), the processor is further configured to estimate an approach probability that the pedestrian will enter the road after a predetermined time based on the pedestrian information, carry out the determination processing determine so that the pedestrian will enter the road when the approach probability exceeds a predetermined criterion value, and change the criterion value based on the generated status information.

(3) In the determining device of embodiment (2), the pedestrian information includes information representing the pedestrian's age or the pedestrian's luggage.

(4) In any one of the determining devices of embodiments (1) to (3), the processor is further configured to change the criterion for the determination processing so that it is easier to determine that the pedestrian will enter the road when the status information represents that the vehicle reduced its speed, a line of sight of the driver was directed to the pedestrian, or the vehicle steered away from a position of the pedestrian.

(5) In any one of the determining devices of embodiments (1) to (3), the processor is further configured to change the criterion for the determination processing so that it is easier to determine that the pedestrian will not enter the road when the status information represents that the vehicle increased its speed or a line of sight of the driver was not directed to the pedestrian.

The determining device according to the present disclosure can accurately determine whether a pedestrian will enter a road based on the status of a driver or a vehicle that can be confirmed by the pedestrian together with the status of the pedestrian.

The object and aspects of the present disclosure will be realized and attained by the elements and combinations particularly specified in the claims. It is to be understood that both the foregoing general description and the following detailed description are exemplary and explanatory, and are not restrictive of the present disclosure as claimed.

### BRIEF DESCRIPTION OF DRAWINGS

FIG. 1 is a diagram illustrating operation of a determining device of the embodiment in overview.

FIG. 2 is a hardware configuration diagram for a vehicle in which the determining device of the embodiment is mounted.

FIG. 3 is an example of an operation flow chart for changing processing by a determining device according to the embodiment.

FIG. 4 is an example of an operation flow chart for generation processing by the determining device according to the embodiment.

FIG. 5 is an example of an operation flow chart for determination processing by the determining device according to the embodiment.

### DESCRIPTION OF EMBODIMENTS

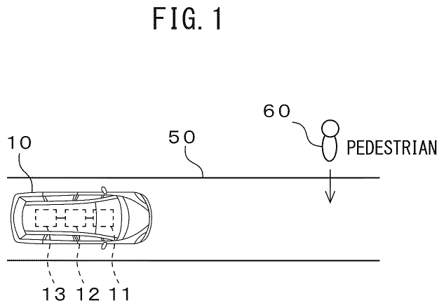

FIG. 1 is a diagram illustrating operation of a determining device of the embodiment in overview. Operation relating to determination processing by a determining device 13 of the embodiment as disclosed herein will now be described in overview with reference to FIG. 1

As shown in FIG. 1, a vehicle 10 is traveling on a road 50. The vehicle 10 has an object detecting device 11, an automatic control device 12, and a determining device 13. The object detecting device 11 detects pedestrian information representing a pedestrian 60 in a predetermined range in the traveling direction of the vehicle 10 based on environmental information representing the environment around the vehicle 10 such as a camera image. In the example shown in FIG. 1, the object detecting device 11 detects the position of the pedestrian 60 with respect to the vehicle 10 as the pedestrian information.

The object detecting device 11 also detects road information representing a road in a predetermined range in the traveling direction of the vehicle 10 based on the environmental information. The object detecting device 11 detects the position of the lane marking line of the road 50 as the road information. The automatic control device 12 controls the vehicle 10 based on the road information, the pedestrian information etc. The vehicle 10 may be an automated driving vehicle.

The determining device 13 carries out determination processing of whether the pedestrian 60 will enter the road 50 based on the road information and the pedestrian information. The determining device 13 notifies the automatic controller 12 of the result of the determination processing. The automatic control device 12 controls the vehicle 10 based on the result of the determination processing.

The determining device 13 generates status information representing a status of a driver (not shown) driving the vehicle 10 that can be confirmed by the pedestrian 60 during a predetermined period in the past. Further, the determining device 13 generates status information representing a status of the vehicle 10 that can be confirmed by the pedestrian 60 during a predetermined period in the past.

The determining device 13 changes the criterion for the determination processing so that it is easier to determine that the pedestrian 60 will enter the road 50 when the status information represents that the vehicle 10 reduced its speed, a line of sight of the driver was directed to the pedestrian 60, or the vehicle 10 steered away from a position of the pedestrian 60.

When the pedestrian 60 confirms that the vehicle 10 reduced its speed, a line of sight of the driver was directed to the pedestrian 60, or the vehicle 10 steered away from a position of the pedestrian 60, it is believed that the pedestrian 60 will determine that the vehicle 10 confirms that the pedestrian 60 will cross the road 50. The pedestrian 60 tries to actively cross the road 50.

On the other hand, the determining device 13 changes the criterion for the determination processing so that it is easier to determine that the pedestrian 60 will not enter the road when the status information represents that the vehicle 10 increased its speed or a line of sight of the driver was not directed to the pedestrian 60.

When the pedestrian 60 confirms that the vehicle 10 increased its speed or a line of sight of the driver was not directed to the pedestrian 60, it is believed that the pedestrian 60 will determine that the vehicle 10 does not confirm that the pedestrian 60 will cross the road 50. The pedestrian 60 is passive in crossing the road.

Therefore, the determining device 13 carries out the determination processing of whether the pedestrian 60 will enter the road 50 using the changed criterion of the determination processing based on the road information and the pedestrian information, considering the interaction of the motion of the pedestrian and the motion of the vehicle based on the status information.

As described above, the determining device 13 can accurately determine whether the pedestrian 60 will enter the road 50 based on the status of the driver or/and the vehicle 10 that can be confirmed by the pedestrian 60 together with the status of the pedestrian 60.

The determining device 13 may notify the driver 50 that the pedestrian 60 will enter the road 50 when it is determined that the pedestrian 60 will enter the road 50. Further, when the determining device 13 determines that the pedestrian 60 will enter the road 50, the automatic control device 12 may decelerate or stop the vehicle 10. Thus, safety of the pedestrian 60 and the vehicle 10 is ensured.

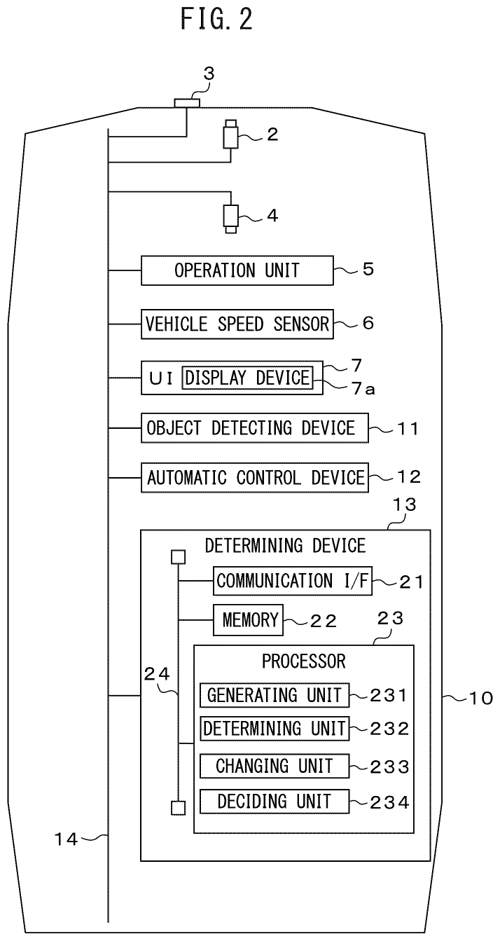

FIG. 2 is a hardware configuration diagram for the vehicle 10 in which the determining device 13 of the embodiment is mounted. The vehicle 10 has s a front camera 2, a millimeter wave radar 3, a monitoring camera 4, an operating unit 5, a vehicle speed sensor 6, a user interface (UI) 7, an object detecting device 11, an automatic control device 12, a determining device 13, etc. The vehicle 10 may further have another ranging sensor such as a LiDAR sensor.

The front camera 2, the millimeter wave radar 3, the monitoring camera 4, the operating unit 5, the vehicle speed sensor 6, UI 7, the object detecting device 11, the automatic control device 12, and the determining device 13 are communicatively connected via an in-vehicle network 14 conforming to a standard such as a controller area network.

The front camera 2 is an example of an imaging unit provided in the vehicle 10. The front camera 2 is mounted on the vehicle 10 and directed toward the front of the vehicle 10. The front camera 2 acquires a camera image in which the environment of a region in a predetermined visual field ahead of the vehicle 10 is shown, at a camera image acquisition time set with a predetermined cycle, for example. The camera image can show the road in the predetermined region ahead of the vehicle 10, and road features such as surface lane marking lines on the road. The front camera 2 has a 2D detector composed of an array of photoelectric conversion elements with visible light sensitivity, such as a CCD or C-MOS. The front camera 2 also has an imaging optical system that forms an image of the photographing region on the 2D detector. The visual field of the front camera 2 is an example of a predetermined range.

Each time a camera image is acquired, the front camera 2 outputs the camera image and the camera image acquisition time through the in-vehicle network 14 to the object detector 11. At the object detector 11, the camera image is used for processing to detect objects and road features surrounding the vehicle 10.

The millimeter-wave radar 3 is mounted on the outer side of the vehicle 10, for example, being directed toward the front of the vehicle 10. The millimeter wave radar 3 emits a scanning millimeter wave toward the predetermined visual field in front of the vehicle 10, at a reflected wave information acquisition time set with a predetermined cycle. Then, millimeter wave radar 3 also receives a reflected wave that has been reflected from a reflector. The information of the time required for the reflected wave to return has information for the distance between the vehicle 10 and other objects located in the direction in which the millimeter wave was emitted. The millimeter wave radar 3 outputs the reflected wave information, together with the reflected wave information acquisition time at which the millimeter wave was emitted, through the in-vehicle network 14 to the object detector 11. The reflected wave information includes the millimeter wave radiation direction and the time it takes for the reflected wave to return. The reflected wave information acquisition time represents the time when the millimeter wave was emitted. At the object detector 11, the reflected wave information is used for processing to detect objects surrounding the vehicle 10. In some embodiments, the visual field of the millimeter wave radar 3 overlaps with the visual field of the front camera 2.

The monitoring camera 4 is mounted in the vehicle cabin to acquire a monitoring image including the face of the driver driving the vehicle 10. The monitoring camera 4 is disposed, for example, on a steering column. The monitoring camera 4 acquires a monitoring image in which the periphery of the driver's seat is shown, at a monitoring image acquisition time set with a predetermined cycle, for example. The monitoring image is an example of information representing the status of the driver.

The monitoring camera 4 has a two-dimensional detector composed of an array of photoelectric conversion elements with infra-red light sensitivity, such as a CCD or C-MOS, and an imaging optical system that forms the image of the area to be acquired on the two-dimensional detector. Each time a monitoring image is acquired, the monitoring camera 4 outputs the monitoring image and the monitoring image acquisition time through the in-vehicle network 14 to the determining device 13. The monitoring image is used in the determining device 13 for generating the status information representing status of the drive driving the vehicle 10 during a predetermined period in the past that can be confirmed by the pedestrian.

The operation unit 5 has a steering wheel, an accelerator pedal, and a brake pedal. The steering wheel generates a signal corresponding to the steering angle by the driver and outputs the signal to the automatic control device 12 via the in-vehicle network 14. The accelerator pedal generates a signal according to the amount of accelerating by the driver and outputs the signal to the automatic control device 12 via the in-vehicle network 14. The brake pedal generates a signal according to the amount of braking by the driver and outputs the signal to the automatic control device 12 via the in-vehicle network 14.

The vehicle speed sensor 6 detects speed information representing the speed of the vehicle 10. The vehicle speed sensor 6 includes, for example, a measuring unit that measures the rotational speed of the tire of the vehicle 10. The vehicle speed sensor 6 outputs the speed information to the object detecting device 11, the automatic control device 12, the determining device 13, etc., through the in-vehicle network 14. The speed information is used in the process of determining the speed of the vehicle 10 in the object detecting device 11, the automatic control device 12 and the determining device 13. The speed information is an example of information representing the motion of the vehicle.

The UI 7 is an exemplary notification unit. The UI 7 is controlled by the automatic control device 12 and the determining device 13 to notify the driver of the driving information or warning of the vehicle 10. The driving information of the vehicle 10 includes the present position of the vehicle, notifications to the driver, etc. The UI 7 has a display device 7a such as a liquid crystal display or a touch panel to display driving information, etc. The UI 7 may also have a sound-output device (not shown) for notifying the driver of driving information, etc.

The object detection device 11 detects objects around the vehicle 10 and its type based on the camera image. The objects include moving objects such as pedestrians or vehicles. Further, the object detecting device 11 detects road features such as a lane marking line and a traffic signal based on the camera image. The object detecting device 11 may detect the lighting state of the traffic signal. The object detecting device 11 may also detect a road edge.

The object detecting device 11 has, for example, a classifier that detects an object and a road feature represented in an image by inputting a camera image. As the classifier, for example, a deep neural network (DNN) pre-trained to detect an object and a road feature represented in the image from the input image can be used. The object detecting device 11 may use a classifier other than DNN.

The object detecting device 11 may also detect an object around the vehicle 10 based on the reflected wave information. The object detecting device 11 may determine the orientation of the object with respect to the vehicle 10 based on the position of the object in the camera image and determine the distance between the object and the vehicle 10 based on this orientation and the reflected wave information. The object detection device 11 estimates the position of an object, for example, represented in a vehicle coordinate system, based on the present position of the vehicle 10 and the distance and orientation to the object with relative to the vehicle 10. The object detecting device 11 may also track an object detected from the latest image by associating the object detected from the latest camera image with the object detected from the past image according to the tracking process based on the optical flow. The tracked object is given an object identification number. Then, the object detecting device 11 may obtain the trajectory of the object being tracked based on the position of the object in the latest image from the past image. The object detecting device 11 can estimate the speed of the object with respect to the vehicle 10 based on changes in the position of the object with time. Further, the object detecting device 11 can estimate the acceleration of the object based on the change in the speed of the object with time. The object detecting device 11 may determine the position of the road feature in the same manner as described above. The position of a road feature is represented, for example, by the vehicle coordinate system.

The object detecting device 11 notifies the automatic control device 12, etc. of object detection information including information representing the objects and road feature information representing the road features. The object detection information includes information indicating the type of the detected object and information indicating the position, the speed, the acceleration, and the traveling lane. For tracked objects, the object detection information includes an object identification number. The object detecting device 11 outputs the road information including the position of the lane marking line representing the road to the determining device 13 through the in-vehicle network 14. The road information may further include the position of the traffic light and the lighting state of the traffic light. In addition, when a pedestrian is detected, the object detecting device 11 generates pedestrian information including the position of the pedestrian tracked within the most recent predetermined time and outputs the pedestrian information to the determining device 13 through the in-vehicle network 14. The pedestrian information may include the speed, acceleration, and object identification number of the pedestrian.

The automatic control device 12 controls the operation of the vehicle 10. The automatic control device 12 has an automatic operation mode for driving the vehicle 10 in automatic operation and a manual operation mode for controlling the operation of the vehicle 10 based on the operation of the driver. In the automatic operation mode, the automatic control device 12 primarily drives the vehicle 10. In the automatic operation mode, the automatic control device 12 controls the operation such as steering, driving, and braking based on information, etc. detected by the front camera 2 and the millimeter wave radar 3 mounted on the vehicle 10.

In the manual operation mode, the driver primarily drives the vehicle 10. In the manual operation mode, the automatic control device 12 controls the operation of the vehicle 10 such as steering, driving, braking, etc. based on the operation to the operation unit 5 of the driver. In the manual operation mode, the automatic control device 12 controls the motion of the vehicle 10 based on the operation of at least one of the steering wheel, brake pedal or accelerator pedal (not shown) by the driver.

The automatic control device 12 outputs steering signals for controlling steering to a steering device (not shown) via an in-vehicle network 14. The automatic control device 12 outputs drive signals for controlling the drive to a drive device (not shown) via an in-vehicle network 14. The automatic control device 12 outputs braking signals for controlling braking to a braking device (not shown) via an in-vehicle network 14. The steering signal for controlling steering, the drive signal for controlling driving, and the braking signal for controlling braking are examples of information representing the motion of the vehicle.

The determining device 13 carries out generation processing, determination processing, changing processing, and decision processing. For this purpose, the determining device 13 has a communication interface (IF) 21, a memory 22, and a processor 23. The communication interface 21, the memory 22, and the processor 23 are connected via signal wires 24. The communication interface 21 has interface circuitry for connecting the determining device 13 to the in-vehicle network 14.

The memory 22 is an example of a storage unit, and it has a volatile semiconductor memory and a non-volatile semiconductor memory, for example. The memory 22 stores an application computer program and various data to be used for information processing carried out by the processor 23.

All or part of the functions of the determining device 13 are, for example, functional modules implemented by a computer program running on the processor 23. The processor 23 includes a generating unit 231, a determining unit 232, a changing unit 233, and a deciding unit 234. Alternatively, the functional module of the processor 23 may be a dedicated arithmetic circuit provided in the processor 23. The processor 23 has one or more CPUs (Central Processing Units) and their peripheral circuits. The processor 23 may also have other computing circuits such as a logical operation unit, numerical calculation unit or graphics processing unit.

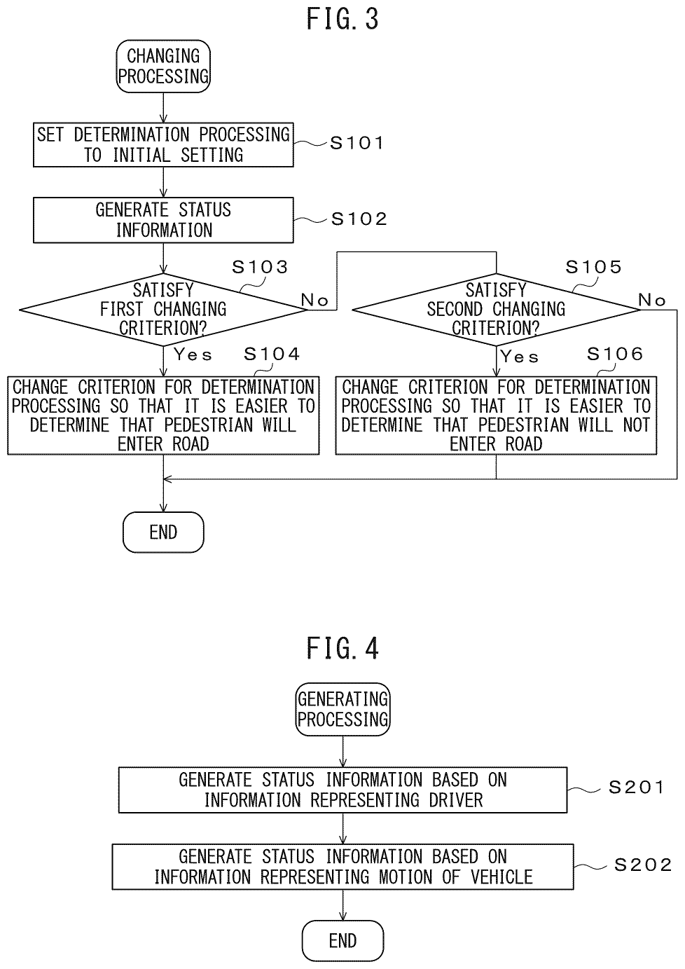

FIG. 3 is an example of an operation flow chart for changing processing by the determining device 13 according to the embodiment. Changing processing by the determining device 13 will now be described with reference to FIG. 3. The determining device 13 carries out changing processing according to the operation flow chart shown in FIG. 3, at a changing time having a predetermined cycle.

First, the changing unit 233 sets the criterion of the determination processing to the initial value (step S101). In the present embodiment, the determining unit 232 has a classifier that estimates an approach probability in which the pedestrian will enter the road after a predetermined time based on the pedestrian information. The approach probability is expressed, for example, as 0.0 to 1.0. The determining unit 232 determines that the pedestrian will enter the road, when the approach probability exceeds a predetermined determination criterion value. The changing unit 233 changes the determination criterion value to the initial value. The initial value of the determination criterion value is, for example, 0.7. The lower the determination criterion value, the easier it is to be determined that a pedestrian will enter the road.

Next, the generating unit 231 generates status information representing a status of a driver driving the vehicle 10 or the vehicle 10 that can be confirmed by the pedestrian during a predetermined period in the past (step S102).

The status information representing the status of the driver driving the vehicle 10 during the predetermined period in the past includes, for example, that a line of sight of the driver was directed to the pedestrian and a line of sight of the driver was not directed to the pedestrian. Before entering the road, the pedestrian observes whether the driver of the approaching vehicle 10 is looking at him/her.

Further, the status information representing the status of the vehicle 10 that can be confirmed by the pedestrian during the predetermined period in the past includes, for example, that the vehicle 10 reduced its speed, the vehicle 10 increased its speed, and the vehicle 10 steered away from a position of the pedestrian. The pedestrian observes the speed and steering direction of the approaching vehicle 10 before entering the road. Processing in which the generating unit 231 generates the status information will be described later.

Next, the changing unit 233 determines whether the status information satisfies the first changing criterion (step S103). The first changing criterion has conditions including that the vehicle 10 reduced its speed, that a line of sight of the driver was directed to the pedestrian, and that the vehicle 10 steered away from a position of the pedestrian. When the status information satisfies any condition of the first changing criterion, the changing unit 233 determines that the status information satisfies the first changing criterion.

When the status information satisfies the first changing criterion (step S103—Yes), the changing unit 233 changes the criterion for the determination processing so that it is easier to determine that the pedestrian will enter the road (step S104), and the series of processing steps is complete. Specifically, the changing unit 233 reduces the determination criterion reference value from the initial value. For example, when the initial value of the determination criterion value is 0.7, the changing unit 233 changes the determination criterion value to 0.5.

When the pedestrian 60 confirms that the vehicle 10 reduced its speed, or that a line of sight of the driver was directed to the pedestrian 60, or that the vehicle 10 steered away from a position of the pedestrian 60, it is believed that the pedestrian 60 will determine that the vehicle 10 confirms that the pedestrian 60 will cross the road 50. The pedestrian 60 try to actively cross the road 50.

On the other hand, when the status information does not satisfy the first changing criterion (step S103—No), the changing unit 233 determines whether the status information satisfies the second changing criterion (step S105). The second changing criterion has conditions including that the vehicle 10 increased its speed and that a line of sight of the driver was not directed to the pedestrian. When the status information satisfies any condition of the second changing criterion, the changing unit 233 determines that the status information satisfies the second changing criterion.

When the status information satisfies the second changing criterion (step S105—Yes), the changing unit 233 changes the criterion for the determination processing so that it is easier to determine that the pedestrian will not enter the road (step S106), and the series of processing steps is complete. Specifically, the changing unit 233 increases the determination criterion value from the initial value. For example, when the initial value of the determination criterion value is 0.7, the changing unit 233 changes the determination criterion value to 0.9.

When the pedestrian 60 confirms the vehicle 10 increased its speed or that a line of sight of the driver was not directed to the pedestrian 60, it is believed that the pedestrian 60 will determine that the vehicle 10 does not confirm that the pedestrian 60 will cross the road 50. The pedestrian 60 is passive in crossing the road.

On the other hand, when the status information does not satisfy the second changing criterion (step S105—No), the series of processing steps is complete. The determining unit 232 carries out the determination processing using the determination criterion value of the initial value.

FIG. 4 is an example of an operation flow chart for generation processing by the determining device 13 according to the embodiment. Generation processing by the determining device 13 will now be described with reference to FIG. 4. The determining device 13 carries out generation processing according to the operation flow chart shown in FIG. 4, at a generation time having a predetermined cycle.

First, the generating unit 231 generates the status information based on information representing the driver of the vehicle 10 (step S201). The generating unit 231 estimates a line of sight of the driver based on the monitoring image. The generating unit 231 has a classifier that has been trained to input a monitoring image and detect predetermined portions such as the inner canthus, the outer canthus, and the center of the pupil as facial feature points. The classifier inputs the monitoring image to detect the type and position of the facial feature points included in the monitoring image.

The classifier has, for example, a deep neural network (DNN) having a plurality of layers connected in series from an input side to an output side. By inputting images containing facial feature points in advance into DNN and performing training using them as teacher data, DNN operates as a classifier to detect the type and position of facial feature points. In addition, a machine learning model such as a support vector machine, a random forest, etc. may be used as the classifier.

The generating unit 231 estimates a direction of the line of sight of the driver using the face feature points. The direction of the line of sight of the driver is expressed by the angle in the horizontal direction with respect to the traveling direction of the vehicle 10. The generating unit 231 may estimate the direction of the line of sight of the driver based on one of the driver's left and right eyes. Further, the generating unit 231 may also estimate the direction of the line of sight for each of the left and right eyes and use their averaged orientation as the direction of the line of sight.

Based on the present position of the vehicle 10 and the position of the pedestrian, the generating unit 231 determines whether the pedestrian is positioned on the left side or the right side with respect to the traveling direction of the vehicle 10.

The generating unit 231 determines whether the direction of the line of sight of the driver is towards the pedestrian. When the position of the pedestrian is on the left side with respect to the traveling direction of the vehicle 10 and the direction of the line of sight of the driver is toward the left side with respect to the traveling direction of the vehicle 10, the generating unit 231 determines that the direction of the line of sight of the driver is towards the pedestrian. The direction of the line of sight of the driver is towards the left side means that, for example, when the traveling direction of the vehicle 10 is defined as 0 degrees, the direction of the line of sight of the driver is in the range of 90 degrees from 0 degrees to the left.

In addition, when the position of the pedestrian is on the right side with respect to the traveling direction of the vehicle 10 and the direction of the line of sight of the driver is toward the right side with respect to the traveling direction of the vehicle 10, the generating unit 231 determines that the direction of the line of sight of the driver is towards the pedestrian. The direction of the line of sight of the driver is towards the right means that, for example, when the traveling direction of the vehicle 10 is defined as 0 degrees, the direction of the line of sight of the driver is in the range of 90 degrees from 0 degrees to the right.

When the direction of the line of sight of the driver is towards the pedestrian for a predetermined reference time or longer during the most recent predetermined monitoring period, the generating unit 231 determines that the direction of the line of sight of the driver is towards the pedestrian. The generating unit 231 generates status information representing that the line of sight of the driver is towards the pedestrian. The monitoring period may be, for example, 5 seconds, while the reference time may be, for example, 3 seconds.

On the other hand, when the direction of the line of sight of the driver is not towards the pedestrian for a period equal to or longer than the reference time during the most recent monitoring period, the generating unit 231 determines that the direction of the line of sight of the driver is not towards the pedestrian. The generating unit 231 generates status information representing that the line of sight of the driver is not towards the pedestrian.

Next, the generating unit 231 generates status information based on the information representing the motion of the vehicle 10 (step S202), and the series of processing steps is complete. The generating unit 231 determines whether the vehicle 10 reduced its speed or the vehicle 10 increased its speed during the most recent predetermined monitoring period based on the speed information. When the vehicle 10 reduced its speed beyond the reference amount of speed, the generating unit 231 determines that the vehicle 10 reduced its speed. The generating unit 231 generates status information representing that the vehicle 10 reduced its speed. On the other hand, when the vehicle 10 increased its speed beyond the reference amount of speed, the generating unit 231 determines that the vehicle 10 increased its speed. The generating unit 231 generates status information representing that the vehicle 10 increased its speed. The monitoring period may be, for example, 5 seconds, and the reference speed may be, for example, 5 km/h.

The generating unit 231 determines whether the vehicle 10 turned to the left or the vehicle 10 turned to the right or not, based on the steering signal. When the steering angle to the left exceeds the predetermined reference angle during the most recent predetermined monitoring period, the generating unit 231 determines that the vehicle 10 turned to the left. When the steering angle to the right exceeds the reference angle during the most recent monitoring period, the generating unit 231 determines that the vehicle 10 turned to the right. When the steering exceeding the reference angle has not been performed during the most recent predetermined monitoring period, the generating unit 231 determines that the vehicle 10 is not turning. The monitoring period may be, for example 5 seconds, the reference angle may be 5 degrees, for example.

Based on the present position of the vehicle 10 and the position of the pedestrian, the generating unit 231 determines whether the pedestrian is positioned on the left side or the right side with respect to the traveling direction of the vehicle 10. When the position of the pedestrian is opposite to the direction in which the vehicle 10 turned, the generating unit 231 determines that the vehicle 10 steered away from the position of the pedestrian. The generating unit 231 generates status information representing that the vehicle 10 steered away from the position of the pedestrian.

When the position of the pedestrian coincides with the direction in which the vehicle 10 turned, or when the vehicle 10 is not turning, the generating unit 231 generates status information representing that the vehicle 10 is not steered away from the position of the pedestrian. The above is a description of the generation processing.

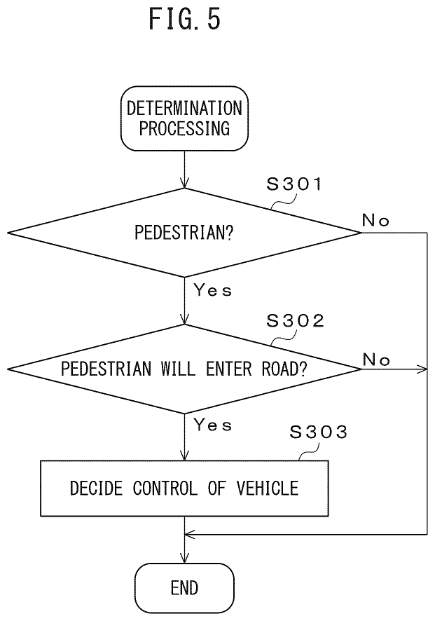

FIG. 5 is an example of an operation flow chart for determination processing by the determining device according 13 to the embodiment. Determination processing by the determining device 13 will now be described with reference to FIG. 5. The determining device 13 carries out determination processing according to the operation flow chart shown in FIG. 5, at a determination time having a predetermined cycle.

First, the determining unit 232 determines whether a pedestrian has been detected (step S301). When the pedestrian information has been input between the previous determination time and the current determination time, the determining unit 232 determines that a pedestrian has been detected. On the other hand, when the pedestrian information has not been input between the previous determination time and the current determination time, the determining unit 232 determines that the pedestrian has not been detected.

When a pedestrian has been detected (step S301—Yes), the determining unit 232 determines whether the pedestrian will enter the road (step S302). Specifically, the determining unit 232 determines whether the pedestrian will enter the road based on the road information representing the road in the predetermined range in the traveling direction of the vehicle 10 and the pedestrian information representing the pedestrian in the predetermined range in the traveling direction of the vehicle 10.

The determining unit 232 has a classifier that estimates an approach probability of the pedestrian entering the road after a predetermined time by inputting the road information and the pedestrian information. The predetermined time, for example, may be 5 seconds. The approach probability is expressed as a value between 0.0 and 1.0. The road information includes at least the position of the lane marking line representing the road. The road information may further include the position of the traffic light and the lighting conditions of the traffic light. The pedestrian information includes the position of the pedestrian tracked during the most recent predetermined time. The classifier has a deep neural network (DNN) that has been pre-trained with the road information and the pedestrian information to estimate the approach probability of the pedestrian entering the road after the predetermined time.

As the pedestrian information, a camera image including the pedestrian may be used. The classifier may also estimate the trajectory of the position of the pedestrian up to a predetermined time later, based on the pedestrian information.

The pedestrian information may also include information about the age of the pedestrian and the information that the pedestrian has luggage, such as a suitcase. When the pedestrian is old person or has luggage, the classifier estimates the approach probability lower than otherwise. The classifier may have a deep neural network (DNN) that has been pre-trained to estimate the approach probability of a pedestrian entering a road after the predetermined time using images representing pedestrians of various ages and pedestrians with luggage.

The determining unit 232 determines that the pedestrian will enter the road, when the approach probability exceeds a determination criterion value. On the other hand, when the approach probability does not exceed the determination criterion value, the determining unit 232 determines that the pedestrian will not enter the road.

When the determining unit 232 determines that the pedestrian will enter the road (step S302—Yes), the deciding unit 234 decides the control of the vehicle 10 (step S303), and the series of processing steps is complete.

When the distance between the present position of the vehicle 10 and the pedestrian is equal to or less than the first reference distance, the deciding unit 234 decides to notify the driver of the warning by using the UI 7. The deciding unit 234, for example, uses the display device 7a to display a warning to the driver. In response to the warning, the driver may manually operate the vehicle 10.

When the distance between the present position of the vehicle 10 and the pedestrian is less than or equal to the second reference distance shorter than the first reference distance, the deciding unit 234 decides stopping the vehicle 10. The decision unit 234 notifies the automatic control device 12 of a stop request to stop the vehicle 10. The automatic control device 12 stops the vehicle 10 in response to the stop request.

When the distance between the present position of the vehicle 10 and the pedestrian is longer than the first reference distance (step S302—No), the series of processing steps is complete. Further, when the pedestrian is not detected (step S301—No), the series of processing steps is complete.

As described above, the determining device of the present embodiment can accurately determine whether a pedestrian will enter a road based on the status of a driver or a vehicle that can be confirmed by the pedestrian together with the status of the pedestrian.

In the present disclosure, the determining device of the embodiment described above may incorporate appropriate modifications that are still within the gist of the disclosure. Moreover, the technical scope of the disclosure is not limited to these embodiments and includes the present disclosure and its equivalents as laid out in the claims.

For example, in the embodiments described above, the status information is shown by way of example and not by way of limitation. Further, in the embodiment described above, changing the determination criterion value of the approach probability is an example of changing the criterion of the determination processing. Changing the criterion of the determination processing is not limited thereto.

Estimation processing of the classifier of the determining unit in the embodiment described above is an example, the estimation processing may be performed using other methods.

In the embodiments described above, the generating processing generates the status information representing a status of a driver driving the vehicle and the vehicle, however the generating processing may generate the status information representing a status of a driver driving the vehicle or the vehicle.

1. A determining device comprising:
a processor configured to
carry out determination processing of whether a pedestrian will enter a road based on road information representing a road and pedestrian information representing a pedestrian, in a predetermined range in a traveling direction of a vehicle,
generate status information representing a status of a driver driving the vehicle or the vehicle that can be confirmed by the pedestrian during a predetermined period in the past, based on information representing the driver of the vehicle or motion of the vehicle,
change criterion for the determination processing based on the generated status information so that it is easier to determine that the pedestrian will enter the road or that the pedestrian will not enter the road, and
wherein the determination processing is carried out whether the pedestrian will enter the road using the changed criterion.

2. The determining device according to claim 1, wherein the processor is further configured to
estimate an approach probability that the pedestrian will enter the road after a predetermined time based on the pedestrian information,
carry out the determination processing determine so that the pedestrian will enter the road when the approach probability exceeds a predetermined criterion value, and
change the criterion value based on the generated status information.

3. The determining device according to claim 2, wherein the pedestrian information includes information representing the pedestrian's age or the pedestrian's luggage.

4. The determining device of claim 1, wherein the processor is further configured to change the criterion for the determination processing so that it is easier to determine that the pedestrian will enter the road when the status information represents that the vehicle reduced its speed, a line of sight of the driver was directed to the pedestrian, or the vehicle steered away from a position of the pedestrian.

5. The determining device of claim 1, wherein the processor is further configured to change the criterion for the determination processing so that it is easier to determine that the pedestrian will not enter the road when the status information represents that the vehicle increased its speed or a line of sight of the driver was not directed to the pedestrian.
